(19) United States
(12) Patent Application Publication
(10) Pub. No.: US 2015/0311067 A1
(43) Pub. Date: Oct. 29, 2015

(54) MILLISECOND ANNEALING IN AMMONIA AMBIENT FOR PRECISE PLACEMENT OF NITROGEN IN THIN FILM STACKS

(71) Applicant: Applied Materials, Inc., Santa Clara, CA (US)

(72) Inventors: Shashank SHARMA, San Jose, CA (US); Jau-Jiun CHEN, San Jose, CA (US); Wolfgang R. ADERHOLD, Cupertino, CA (US); Kai NG, San Jose, CA (US); Houda GRAOUI, Morgan Hill, CA (US); Shankar MUTHUKRISHNAN, San Jose, CA (US); Abhilash J. MAYUR, Salinas, CA (US); Gia PHAM, San Jose, CA (US)

(21) Appl. No.: 14/261,017

(22) Filed: Apr. 24, 2014

(51) Int. Cl. H01L 21/02

(52) U.S. Cl. CPC H01L 21/02337; H01L 21/02351; H01L 21/02354; H01L 21/02345

(57) ABSTRACT

Embodiments of the present disclosure relate to methods for processing a substrate. In one embodiment, the method includes forming a dielectric layer over a substrate, wherein the dielectric layer has a dielectric value of about 3.9 or greater, heating the substrate to a first temperature of about 600 degrees Celsius or less by a heater of a substrate support disposed within a process chamber, and incorporating nitrogen into the dielectric layer in the process chamber by annealing the dielectric layer at a second temperature between about 650 and about 1450 degrees Celsius in an ambient nitrogen environment, wherein the annealing is performed on the order of millisecond scale.

### FIELD

Embodiments of the present disclosure generally relate to semiconductor fabrication.

### BACKGROUND

Microelectronic devices are fabricated on a semiconductor substrate as integrated circuits in which various conductive layers are interconnected with one another to permit electronic signals to propagate within the device. An example of such a device is a complementary metal-oxide-semiconductor (CMOS) field effect transistor (FET) or MOSFET. In a CMOS transistor, for example, the semiconductor material is engineered to create a gate structure disposed between a source region and a drain region that are formed in the semiconductor material. The gate structure generally includes a gate electrode and a gate dielectric. The gate electrode is disposed over the gate dielectric to control a flow of charge carriers in a channel region that is formed between drain and source regions beneath the gate dielectric. The gate dielectric typically includes a thin material layer having a dielectric constant of about 4.0, for example, gate oxides such as silicon dioxide (SiO₂). The gate dielectric serves as an insulator to prevent large leakage currents from flowing into the channel region between the gate electrode and the channel region.

Recent transistor scaling efforts have focused on high-K dielectric materials having a dielectric constant greater than that of SiO₂. High-K dielectric materials can be formed in a thicker layer (i.e., bulk high-K dielectric) than SiO₂, and yet still reduce gate leakage current and produce equivalent field effect performance. To prevent undesirable interactions between the bulk high-K dielectric and underlying semiconductor material (usually silicon) which degrades carrier mobility, a thin silicon oxide layer (interlayer) is typically employed between the high-K dielectric material and the semiconductor material. The bulk high-K dielectric can also be provided with a uniform nitrogen concentration to stabilize the high-K dielectric while blocking diffusion of boron or other impurities implanted in the overlying gate electrode material. However, the introduction of nitrogen into the bulk high-K dielectric may have other deleterious effects on the underlying semiconductor material, such as nitrogen diffusion into the interlayer, resulting in poor device characteristics.

Therefore, there is a need in the art to provide an improved fabrication technique for shallow nitrogen incorporation to prevent undesired diffusion of nitrogen into the interlayer.

### SUMMARY

Embodiments of the present disclosure relate to methods for processing a substrate. In one embodiment, the method includes incorporating nitrogen into a dielectric layer formed over a substrate in a process chamber by annealing the dielectric layer at a temperature between about 650 and about 1450 degrees Celsius in an ambient ammonia environment, wherein the annealing is performed using a laser beam having a wavelength between about 200 nm and about 20 micrometers and a dwell time of about 0.01 milliseconds to about 1000 milliseconds.

In another embodiment, the method includes forming a dielectric layer over a substrate, wherein the dielectric layer has a dielectric value of about 3.9 or greater, heating the substrate to a first temperature of about 600 degrees Celsius or less by a heater of a substrate support disposed within a process chamber (or by other means like lamp heating or inductive heating), and incorporating nitrogen into the dielectric layer in the process chamber by annealing the dielectric layer at a second temperature between about 650 and about 1400 degrees Celsius in an ambient ammonia environment, wherein the annealing is performed on the order of millisecond scale.

In one another embodiment, the method includes forming a dielectric layer over a substrate, and incorporating nitrogen into the dielectric layer in a process chamber by delivering a constant energy flux from an energy source to a desired region on a surface of the dielectric layer in an ambient ammonia environment, wherein the constant energy flux is delivered on the order of millisecond scale.

In yet another embodiment, the method includes forming a dielectric layer over a substrate, heating the substrate to a first temperature of about 600 degrees Celsius or less by a heater of a substrate support disposed within a process chamber, and annealing the dielectric layer formed over the substrate in the presence of a nitrogen-containing gas for a period of about 0.1 milliseconds to about 10 milliseconds.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. It is to be noted, however, that the appended drawings illustrate only typical embodiments of this disclosure and are therefore not to be considered limiting of its scope, for the present disclosure may admit to other equally effective embodiments.

FIG. 1 depicts a flow chart of a method for manufacturing a gate stack structure according to embodiments of the disclosure.

FIG. 2 shows a cross-sectional view of an exemplary, simplified gate stack structure manufactured according to embodiments of the disclosure.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present disclosure provide methods for placing nitrogen precisely in a single film (HfO₂, ZrO₂, TiN, SiO₂, etc.) or a film stack comprising of at least two layers A, B (and possibly C), where A, B, and C could be any combination of materials like oxides and nitrides. The inventive methods may be utilized in the manufacture of semiconductor devices such as transistors used for amplifying or switching electronic signals. For example, the film manufactured according to embodiments of the disclosure may be used in a gate structure for metal oxide semiconductor field effect transistors (MOSFETs). While embodiments described herein use a gate stack structure as an example, it should be understood that embodiments of the disclosure may also be applied to any integral circuit devices incorporating high-K dielectric films, or any integral circuit devices having a dielectric film.

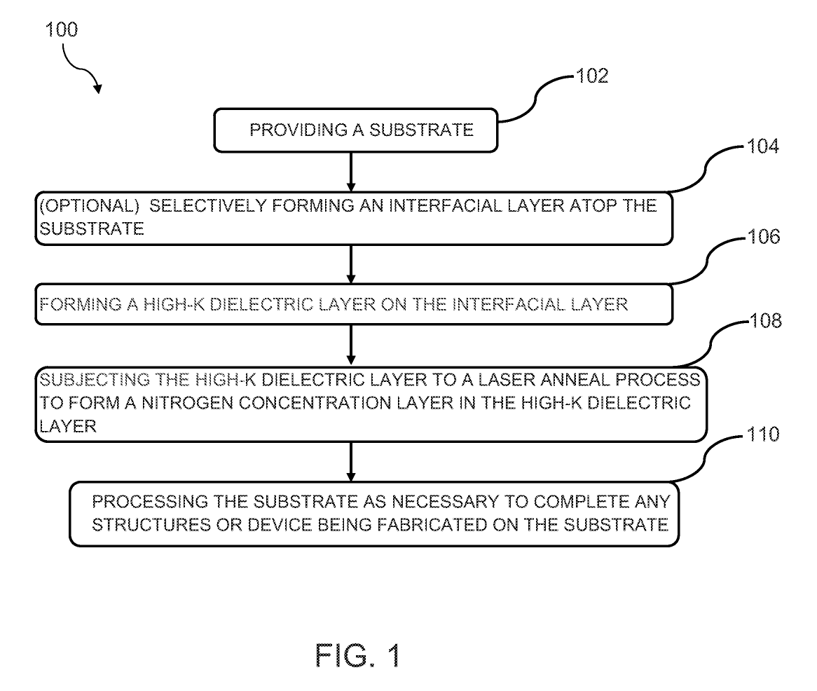

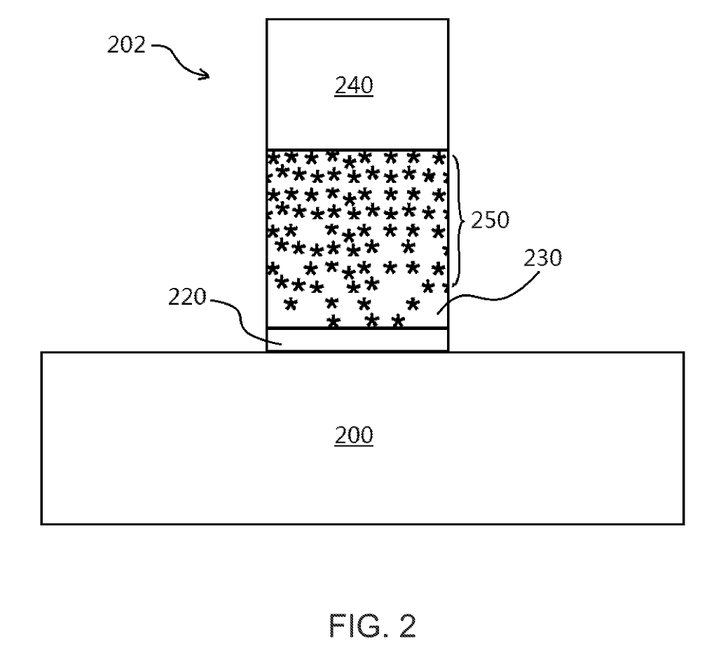

FIG. 1 depicts a flow chart of a method 100 for manufacturing a gate stack structure according to embodiments of the disclosure. FIG. 1 is illustratively described with reference to FIG. 2, which shows a cross-sectional view of an exemplary, simplified gate stack structure manufactured according to embodiments of the disclosure. The method 100 begins at block 102, where a substrate 200 is provided having a gate structure 202 to be formed thereupon. The gate structure 202 may have one or more layers formed on a substrate 200. For example, the gate structure 202 may include, among others, a dielectric layer 230, a metal gate layer 240 disposed above the dielectric layer 230, and an interfacial layer 220 disposed between the dielectric layer 230 and the substrate 200, as shown in FIG. 1. While not shown, it is contemplated that the gate structure 202 may optionally include one or more material layers disposed on the metal gate layer 240, such as a polysilicon layer, a tungsten-containing layer, etc., depending upon the application.

In the following description, the term substrate is intended to broadly cover any object that is being processed in a process chamber. The substrate 200 may be any substrate capable of having material deposited thereon, such as a silicon substrate, for example silicon (doped or undoped), crystalline silicon (e.g., Si<110> or Si<111>), silicon oxide, strained silicon, doped or undoped polysilicon, or the like, germanium, a III-V compound substrate, a silicon germanium (SiGe) substrate, an epi substrate, a silicon-on-insulator (SOI) substrate, a carbon doped oxide, a silicon nitride, a display substrate such as a liquid crystal display (LCD), a plasma display, an electro luminescence (EL) lamp display, a solar array, solar panel, a light emitting diode (LED) substrate, a patterned or non-patterned semiconductor wafer, glass, sapphire, or any other materials such as metals, metal alloys, and other conductive materials. The substrate 200 may include dielectric materials such as silicon dioxide and carbon dopes silicon oxides. In some embodiments, the substrate 100 may include a p-type or n-type region defined therein (not shown). Additionally or alternatively, the substrate 100 may include a plurality of field isolation regions (not shown) formed in the substrate 100 to isolate wells having different conductivity types (e.g., n-type or p-type) and/or to isolate adjacent transistors (not shown). The field isolation regions may be shallow trench isolation (STI) structures formed, for example, by etching a trench into the substrate 100 and then filling the trench with a suitable insulator, such as silicon oxide (oxide), silicon nitride (nitride), or the like.

In some embodiments, the substrate 200 may include other structures or features at least partially formed therein. For example, in some embodiments, a feature such as a via, a trench, a dual damascene feature, high aspect ratio feature, or the like, may be formed within the substrate 200 through any suitable process or processes, such as an etch process. In some embodiments, the substrate 200 may include a source region (not shown) and a drain region (not shown) formed in an upper region of the substrate 200, which may be the substrate surface, by implanting ions into the substrate 200. In such a case, the source region and the drain region may be bridged by the metal gate layer 240. While not shown, an off-set layer or spacer may be optionally deposited on both sides of the gate structure 202. The spacer may contain silicon nitride, silicon oxynitride, derivatives thereof, or combinations thereof.

At block 104, an optional interfacial layer 220 is selectively formed atop the substrate 200, as shown in FIG. 1. The interfacial layer 220 may include silicon and oxygen, such as silicon oxide (SiO₂), silicon oxynitride (SiON), or the like. The interfacial layer 120 may have a thickness of about 2 Å to about 80 Å. The interfacial layer 220 may be formed using suitable plasma oxidation or thermal oxidation methods. For example, the interfacial layer 220 may be formed thermally in an oxygen-containing environment, such as in an environment containing oxygen (O₂), ozone (O₃), water vapor (H₂O), hydrogen plus oxygen (H₂+O₂), or the like. An inert gas, such as helium (He), argon (Ar), nitrogen (N₂), ammonia (NH₃) or the like, may optionally be used.

At block 106, a dielectric layer 230 is formed on the interfacial layer 220 (if used), as shown in FIG. 1. The dielectric layer 230 may have a thickness ranging from about 5 Å to about 100 Å, for example about 20 Å. The dielectric layer 230 may be a single film using the material listed below, or a film stack comprising two or more layers, where the layers could be any combination of materials like oxides and nitrides, or any combination of materials listed below. In one embodiment, the dielectric layer 230 may be a high-K dielectric material having a dielectric value greater than about 3.9. Suitable materials for the dielectric layer 230 may include, but are not limited to hafnium oxide (HfOₓ), hafnium silicon oxide (HfSiOₓ), hafnium silicon oxynitride (HfSiOₓN_{y}), hafnium aluminium oxide (HfAlOₓ), aluminum oxide (Al₂O₃), tantalum pentoxide (Ta₂O₅), titanium dioxide (TiO₂), zirconium oxide (ZrO₂), hafnium zirconium oxide (HfZrO₂), lanthanum oxide (La₂O₃), yttrium oxide (Y₂O₃) and their aluminates and silicates. The dielectric layer 230 may be other materials such as titanium aluminum alloy, tantalum aluminum alloy, titanium nitride, titanium silicon nitride, titanium aluminum nitride, tantalum nitride, tantalum silicon nitride, hafnium nitride, hafnium silicon nitride, aluminum nitride, or a combination thereof. Depending upon the material of the layer to be formed, a suitable process, such as wet or dry thermal oxidation process, chemical vapor deposition (CVD) techniques, plasma enhanced chemical vapor deposition (PECVD) techniques, physical vapor deposition (PVD) techniques, atomic layer deposition (ALD) techniques, or combinations thereof, may be used to form the dielectric layer 230.

At block 108, the dielectric layer 230 is subjected to a nitridation process to form a nitrogen concentration layer 250 in the dielectric layer 230, as shown in FIG. 1. The nitrogen concentration layer 250 may have a thickness and concentration suitable to prevent the diffusion of undesired dopants into the underlying substrate 200. For example, the nitrogen concentration layer 250 may have an overall thickness of about 5 Å to about 20 Å measuring from the top surface of the dielectric layer 230. Upon completion of the nitridation process, the nitrogen concentration layer 250 generally has a gradient distribution of nitrogen decreasing from the top surface to the bottom surface of the dielectric layer 230. For example, the nitrogen concentration layer 250 may have a relatively large nitrogen concentration (e.g., about 80%-99% by weight of a total weight of the nitrogen atoms) exhibited in the dielectric layer 230 at or near the top surface of the dielectric layer 230, for example the dielectric layer 230metal gate layer 240 interface, and a relatively small or minimized nitrogen concentration (e.g., about 1%-20% by weight of a total weight of the nitrogen atoms) exhibited in the dielectric layer 230 at or near the bottom surface of the dielectric layer 230, for example the dielectric layer 230/substrate 200 interface, or the dielectric layer 230/interfacial layer 220 interface if the interfacial layer 220 were used. The nitrogen concentration layer 250 is formed to stabilize the dielectric layer 230 and provide a barrier against undesired diffusion from the overlying layers (such as the metal gate layer 240) into the underlying substrate. At the same time, however, high concentrations of nitrogen at the dielectric layer 230 may also lead to mobility degradation due to uncompleted bonds, or undesired nitrogen diffusion into the underlying substrate. To maintain a desired nitrogen concentration and prevent diffusion of nitrogen into the underlying substrate, the inventors have proposed to provide controlled nitrogen concentration uniformity in the dielectric layer 230 at concentrations able to successfully inhibit dopant diffusion and stabilize the dielectric layer 230, while also providing lower or minimized nitrogen concentration at the interface between the dielectric layer 230 and the interfacial layer 220. Particularly, the inventive nitridation process ensures that the nitrogen does not diffuse into the underlying substrate 200.

In one embodiment, the nitridation process is performed in a controlled ambient ammonia environment by using an anneal process in the presence of ammonia gas flowed into the process chamber. The ammonia fraction in the ambient nitrogen environment can be varied from about 1% to 100%. Anneal processes described herein refer to those processes performed at a temperature that is greater than about 600 degrees Celsius, with a temperature of greater than about 700 degrees Celsius being more typical. Anneal processes can be carried out using laser anneal processes, spike anneal processes, rapid thermal anneal processes, and/or furnace anneal processes. In one embodiment of the present disclosure, the nitrogen concentration layer 250 is formed using a laser anneal process. In one example, the laser anneal process is a dynamic surface anneal (DSA) process. Laser anneal processes may deliver a constant energy flux from an energy source to a small region on the surface of the substrate while the substrate is translated, or scanned, relative to the energy (or vice versa) delivered to the small region. The energy source may deliver electromagnetic radiation energy to perform the annealing process at desired regions of the substrate. Typical sources of electromagnetic radiation energy include, but are not limited to, an optical radiation source, an electron beam source, an ion beam source, and/or a microwave energy source, any of which may be monochronistic or polychronistic and may have any desired coherency. In one embodiment, the energy source is an optical radiation source using one or more laser sources. The lasers may be any type of laser such as gas laser, excimer laser, solid-state laser, fiber laser, semiconductor laser etc., which may be configurable to emit light at a single wavelength or at two or more wavelengths simultaneously.

The laser anneal process may take place on a given region of the substrate for a relatively short time, such as on the order of about one second or less. In various embodiments, the laser anneal process is performed on the order of millisecond. Millisecond annealing provides improved yield performance and improved junction leakage performance due to fewer leakage-inducing defects through steep temperature profile. Millisecond annealing process therefore enables precise control of the placement of nitrogen in the dielectric layer 230 while minimizing the diffusion of the nitrogen into underlying layers.

The laser anneal process may be performed in any suitable process chamber, or combination of process chambers suitable for forming and annealing the dielectric layer 230. Such suitable chambers include any chamber capable of performing laser anneal or dynamic surface anneal (DSA), flash anneal, rapid thermal processing (RTP) such as spike or soak RTP, or combinations thereof. One exemplary chamber is the Astra DSA® chamber available from Applied Materials, Inc. of Santa Clara, Calif. Each process chamber used to practice embodiments of the disclosure may be operated individually, or as part of a cluster tool, such as one of the CENTURA® line of cluster tools, available from Applied Materials, Inc. of Santa Clara, Calif.

In some embodiments, prior to the laser anneal process, the process chamber (e.g., DSA chamber) may be purged with a suitable purge gas, such as nitrogen, to reduce oxygen concentration to less than 10 ppm (parts per million) in a nitrogen environment. Thus, the growth of interface oxide is restricted. The purge gas may then be turned off, or may continue to flow if the nitrogen-containing gas to be used in the subsequent laser anneal process is also nitrogen.

The laser anneal process may include providing a laser beam which may be applied sequentially to at least some portions of the object being annealed, for instance, the dielectric layer 230 of the gate structure 202. In operation, the laser beam may anneal a first portion of the dielectric layer 230 for a desired time, the substrate 200 and/or laser beam may be moved, and the laser beam may anneal a second portion of the dielectric layer 230 for a desired time. The laser beam may be operated in a pulsed or continuous mode and over a desired range of wavelengths and intensities. In one embodiment, the laser beam may have a wavelength between about 200 nm and about 20 micrometers, such as between about 700 nm and 1200 nm, for example about 810 nm, and an energy density of about 0.1 W/cm² to about 10 W/cm². The laser beam may have a short dwell time of about 0.01 milliseconds to about 1000 milliseconds, such as about 0.1 milliseconds to about 100 milliseconds, for example about 0.1 milliseconds to about 10 milliseconds, such as about 0.2 milliseconds to about 5 milliseconds. The dwell time should be short to avoid substrate bow and breakage. Such conditions may be adjusted depending on, for instance, the absorbing properties (e.g., absorption cross section, extinction coefficient, or the like) of the material being annealed, and the speed of the substrate being translated, or scanned, relative to the laser beam delivered to the desired region of the substrate. The dwell time of the laser beam can be varied, by either varying the speed of the laser motion or by repeating the exposures. In either case, laser scan rates may range in the 25 mm/sec to 350 mm/sec to achieve these millisecond dwell times. It is contemplated that the laser anneal process may be nanosecond annealing processes, microsecond annealing processes or flash lamp annealing processes including xenon flash lamp annealing processes.

In some embodiments, the nitrogen-containing gas may include, but is not limited to, ammonia (NH₃), nitrogen (N₂), hydrazine (N₂H₄), and mixtures thereof. In some embodiments, the nitrogen-containing gas may include a gas mixture comprising NH₃ and N₂ or a gas mixture comprising NH₃ and H₂. In certain embodiments, hydrazine (N₂H₄) may be used in place of or in combination with NH₃ in the gas mixture with N₂ and H₂. In some embodiments, the nitrogen-containing gas may use nitric oxide (NO), nitrous oxide (N₂O), or nitrogen dioxide (NO₂). Alternatively, the nitrogen-containing gas may include lower substituted hydrazines (N₂R₂, wherein each R is independently hydrogen, a methyl, ethyl, propyl, vinyl, or propenyl group), and lower amines (NRₐH_{b}, wherein a and b are each integers from 0 to 3 and a+b=3, and each R is independently hydrogen, a methyl, ethyl, propyl, vinyl, or propenyl group), amides (RCONR′R″, wherein R, R′, and R″ are each independently hydrogen, a methyl, ethyl, propyl, vinyl, or propenyl group), imines (RR′C═NR″, wherein R, R′, and R″ are each independently hydrogen, a methyl, ethyl, propyl, vinyl, or propenyl group), or imides (RCONR′COR″, wherein R, R′, and R″ are each independently hydrogen, a methyl, ethyl, propyl, vinyl, or propenyl group). In such a case, the nitrogen-containing gas may be optionally mixed with non-reactive gases, such as one or more of nitrogen gas (N₂), helium (He), argon (Ar), neon (Ne), xenon (Xe), or the like.

During the laser anneal process, the chamber pressure may be maintained at about 1 Torr to about 760 Torr. The temperature of each portion having the laser beam incident thereon may be up to about 1350 degrees Celsius. The peak temperature of each portion having the laser beam incident thereon may be between about 600 to about 1412 degrees Celsius. In various embodiments, the heater temperature of the substrate support upon which the substrate 200 is disposed may vary from room temperature to about 800 degrees Celsius. The heater flexibility provides the ability to set the heater temperature either below or above the temperature to which the substrate has been exposed in the previous process steps. An electrostatic chuck may be used for reduced pressure processes.

The substrate 200 may be exposed to the heater temperature throughout the laser anneal process. In some embodiments, the substrate 200 may be preheated to about 600 degrees Celsius or less, such as about 300 degrees Celsius or less, about 250 degrees Celsius or less, for example about 100 degrees Celsius or less, thereby improving the surface properties of the materials on the substrate. The pre-heat temperature should be low enough to avoid uncontrolled diffusion. Once the desired pre-heat temperature is achieved, the laser beam is initiated to heat the desired region of the substrate 200, i.e., the dielectric layer 230. The laser beam may have a beam temperature of about 600 degrees Celsius to about 1350 degrees Celsius. The beam temperature should be high enough to enable optimal activation/annealing process without breakage of the substrate. In some embodiments, the heater temperature may be from about 100 degrees Celsius to about 600 degrees Celsius, and the laser beam temperature may be from about 650 degrees Celsius to about 1450 degrees Celsius. For example, the heater temperature may be from about 100 degrees Celsius to about 300 degrees Celsius, and the laser beam temperature may be from about 600 degrees Celsius to about 1000 degrees Celsius. In some examples, the heater temperature may be from about 300 degrees Celsius to about 600 degrees Celsius, and the laser beam temperature may be from about 700 degrees Celsius to about 1350 degrees Celsius. In some cases, the laser anneal process may heat the dielectric layer 230 near the melting point, without actually causing a liquid slate. The nitrogen from the nitrogen-containing gas is then incorporated into the dielectric layer 230 under high thermal energy supplied by the laser beam by a high-pressure nitrogen ambient in the process chamber. If desired, the laser anneal process may be repealed until a desired nitrogen profile has formed within the dielectric layer 230. In one example, the nitrogen concentration layer 250 may have a concentration of about 1×10¹⁸ atoms/cm³ or greater, such as about 1.6×10²⁰ to about 1.4×10²¹, at or near the top surface of the dielectric layer 230, and a concentration of about 1×10¹⁵ atoms/cm³ or less, at or near the bottom surface of the dielectric layer 230.

Alternatively, in some embodiments, the nitridation process may be performed by using a flash anneal in the presence of the nitrogen-containing gas (as discussed above) at a temperature greater than about 950 degrees Celsius. In some embodiments, the temperature may be up to about 1350 degrees Celsius. In some embodiments, the temperature may between about 900 and about 1450 degrees Celsius. The time of the flash anneal process may be defined as the time that, for instance, the dielectric layer 230 is exposed to the radiant energy of an arc lamp of a flash anneal system. In some embodiments, the exposure time is about 0.1 milliseconds to about 10 milliseconds, for example about 0.5 milliseconds to about 8 milliseconds. In some embodiments, the exposure time may be between about 2 milliseconds to about 5 milliseconds. Other suitable annealing processes, such as spike rapid thermal anneal or a soak rapid thermal anneal process, may also be used.

At block 110, upon completion of the laser anneal process at block 108, the substrate 200 may be further processed as necessary to complete any structures or device being fabricated thereon. For example, a metal gate layer 240 may be formed on the dielectric layer 230. The metal gate layer 240 may have a thickness suitable to provide the appropriate work function for the semiconductor device being processed. For example, the metal gate layer 240 may have a thickness of about 10 Angstroms (Å) to several hundred Å, for example about 20 Å to about 100 Å. The metal gate layer 240 may include a metal, a metal alloy, a metal nitride, a metal silicide, or a metal oxide. In some embodiments, the metal gate layer 240 may contain titanium, titanium aluminum alloy, tantalum, tantalum aluminum alloy, titanium nitride, titanium silicon nitride, titanium aluminum nitride, tantalum nitride, tantalum silicon nitride, hafnium nitride, hafnium silicon nitride, aluminum nitride, aluminum oxide, tungsten, platinum, aluminum, ruthenium, molybdenum, other conductive materials, or a combination thereof. Depending upon the material of the layer to be formed, a suitable process, such as chemical vapor deposition (CVD) techniques, plasma enhanced chemical vapor deposition (PECVD) techniques, physical vapor deposition (PVD) techniques, atomic layer deposition (ALD) techniques, or combinations thereof, may be used to form the metal gate layer 240.

Benefits of the invention include a fast, shallow nitrogen incorporation into a layer using a millisecond annealing process in a controlled ambient ammonia environment. Millisecond annealing process provides improved yield performance and improved junction leakage performance due to fewer leakage-inducing defects through steep temperature profile. Millisecond annealing process therefore enables precise control of the placement of nitrogen in a layer formed over a substrate while minimizing the diffusion of the nitrogen into underlying layers.

While the foregoing is directed to embodiments of the present disclosure, other and further embodiments of the disclosure may be devised without departing from the basic scope thereof.

1. A method of processing a substrate, comprising:
incorporating nitrogen into a dielectric layer formed over a substrate in a process chamber by annealing the dielectric layer at a temperature between about 650 and about 1450 degrees Celsius in an ambient ammonia environment, wherein the annealing is performed using a laser beam having a wavelength between about 200 nm and about 20 micrometers and a dwell time of about 0.01 milliseconds to about 1000 milliseconds, and the dielectric layer has a dielectric constant greater than about 3.9.

2. A method of processing a substrate, comprising:
forming a dielectric layer over a substrate; and
incorporating nitrogen into the dielectric layer in a process chamber by delivering a constant energy flux from an energy source to a desired region on a surface of the dielectric layer in an ambient ammonia environment, wherein the constant energy flux is delivered on the order of millisecond scale of dwell time.

3. The method of claim 2, wherein the energy source comprises an optical radiation source, an electron beam source, an ion beam source, a microwave energy source, or combinations thereof.

4. The method of claim 2, wherein the energy source is an optical radiation source using one or more laser sources operated in a pulsed or continuous mode.

5. The method of claim 4, wherein the constant energy flux is delivered at a time period of about 0.1 milliseconds to about 100 milliseconds and a chamber pressure of about 1 Torr to about 760 Torr.

6. The method of claim 4, wherein the constant energy flux is delivered at a wavelength of about 200 nm to about 20 micrometers, and an energy density of about 0.1 W/cm² to about 10 W/cm².

7. The method of claim 2, wherein the nitrogen is incorporated into the dielectric layer to form a nitrogen concentration layer having a thickness of about 10 Å to about 100 Å measuring from the surface of the dielectric layer.

8. The method of claim 2, wherein the ambient nitrogen environment is established by flowing a nitrogen-containing gas into the process chamber, the nitrogen-containing gas comprises ammonia (NH₃), nitrogen (N₂), hydrazine (N₂H₄), or mixtures thereof.

9. The method of claim 2, further comprising:
prior to incorporating nitrogen into the dielectric layer, purging the process chamber with a purge gas to reduce oxygen concentration to less than 10 ppm.

10. The method of claim 2, further comprising:
prior to incorporating nitrogen into the dielectric layer, heating the substrate to a first temperature by a heating source.

11. The method of claim 10, wherein the constant energy flux heats the substrate to a second temperature of about 600 degrees Celsius to about 1000 degrees Celsius, or about 700 degrees Celsius to about 1350 degrees Celsius.

12. The method of claim 10, wherein the first temperature is between about room temperature and about 300 degrees Celsius, or about 300 degrees Celsius and about 600 degrees Celsius.

13. The method of claim 2, wherein the dielectric layer comprises hafnium oxide (HfOₓ), hafnium silicon oxide (HfSiOₓ), hafnium silicon oxynitride (HfSiOₓN_{y}), hafnium aluminium oxide (HfAlOₓ), aluminum oxide (Al₂O₃), tantalum pentoxide (Ta₂O₅), titanium dioxide (TiO₂), zirconium oxide (ZrO₂), hafnium zirconium oxide (HfZrO₂), lanthanum oxide (La₂O₃), yttrium oxide (Y₂O₃), or aluminates or silicates of the above, titanium aluminum alloy, tantalum aluminum alloy, titanium nitride, titanium silicon nitride, titanium aluminum nitride, tantalum nitride, tantalum silicon nitride, hafnium nitride, hafnium silicon nitride, aluminum nitride, or a combination thereof.

14. A method of processing a substrate, comprising:
forming a dielectric layer stack over a substrate, wherein the dielectric layer stack comprises at least two layers of dielectric materials each having a dielectric constant greater than about 3.9;
heating the substrate to a first temperature of about 600 degrees Celsius or less by a heater of a substrate support disposed within a process chamber; and
annealing the dielectric layer stack formed over the substrate in the presence of a nitrogen-containing gas for a period of about 0.1 milliseconds to about 10 milliseconds.

15. The method of claim 14, further comprising:
prior to forming the dielectric layer stack, forming an interfacial layer on the substrate in an oxygen-containing environment.

16. The method of claim 14, wherein annealing the dielectric layer stack comprises performing a laser anneal process at a second temperature between about 600 degrees Celsius and about 1350 degrees Celsius.

17. The method of claim 14, wherein annealing the dielectric layer stack comprises performing a flash anneal process at a second temperature between about 900 degrees Celsius and about 1450 degrees Celsius.

18. The method of claim 14, wherein annealing the dielectric layer stack forms a nitrogen concentration layer having a thickness of about 10 Å to about 100 Å measuring from a top surface of the dielectric layer.

19. The method of claim 14, wherein the nitrogen-containing gas comprises ammonia (NH₃), nitrogen (N₂), hydrazine (N₂H₄), or mixtures thereof.

20. The method of claim 14, wherein the dielectric layer stack comprises hafnium oxide (HfOₓ), hafnium silicon oxide (HfSiOₓ), hafnium silicon oxynitride (HfSiOₓN_{y}), hafnium aluminium oxide (HfAlOₓ), aluminum oxide (Al₂O₃), tantalum pentoxide (Ta₂O₅), titanium dioxide (TiO₂), zirconium oxide (ZrO₂), hafnium zirconium oxide (HfZrO₂), lanthanum oxide (La₂O₃), yttrium oxide (Y₂O₃), or aluminates or silicates of the above, titanium aluminum alloy, tantalum aluminum alloy, titanium nitride, titanium silicon nitride, titanium aluminum nitride, tantalum nitride, tantalum silicon nitride, hafnium nitride, hafnium silicon nitride, aluminum nitride, or a combination thereof.
